(19) United States
(12) Patent Application Publication
(10) Pub. No.: US 2009/0251431 A1
(43) Pub. Date: Oct. 8, 2009

(54) Organic light emitting display device

(76) Inventors: Chang-Hoon Lee, Yongin-city (KR); Patrick Lee, Yongin-city (KR); Soo-Hak Seo, Yongin-city (KR); Suh-Jin Yi, Yongin-city (KR); Hyun-Sook Kim, Yongin-city (KR)

Correspondence Address: ROBERT E. BUSHNELL & LAW FIRM, 2029 K STREET NW, SUITE 600, WASHINGTON, DC, 20006-1004, US

(21) Appl. No.: 12/385,310

(22) Filed: Apr. 3, 2009

(30) Foreign Application Priority Data
Apr. 3, 2008 (KR) 10-2008-031086

(51) Int. Cl. G06F 3/041; G09G 3/30

(52) U.S. Cl. 345/173; 345/76

(57) ABSTRACT

An organic light emitting display device (OLED display) having a first display panel and a second display panel arranged on the same surface thereof. The OLED display includes first and second display panels arranged on a same surface, a touch screen panel arranged integrally on the first and second display panels, a touch screen panel controller adapted to drive the touch screen panel and a display controller adapted to control the first and second display panels, the display controller being further adapted to separate information displayed on the display panels into an image signal and a data signal corresponding to the image signal, the display controller being further adapted to supply the separated image signal and data signal to the first and second display panels, respectively.

### CLAIM OF PRIORITY

This application makes reference to, incorporates the same herein, and claims all benefits accruing under 35 U.S.C. §119 from an application for ORGANIC LIGHT EMITTING DISPLAY DEVICE earlier filed in the Korean Intellectual Property Office on 3 Apr. 2008 and there duly assigned Serial No. 10-2008-0031086.

### BACKGROUND OF THE INVENTION

1. Field of the Invention

An organic light emitting display device (OLED display) having a first display panel and a second display panel arranged on the same surface thereof, wherein information displayed on the two display panels are realized to be engaged with each other.

2. Description of the Related Art

With the rapid spread of portable terminals, a lot of people are using portable terminals such as mobile phones or personal digital assistants (PDAs). Also, there is an increasing demand for portable terminals that are small, slim and lightweight. Therefore, components installed in the portable terminals are manufactured to have a small size in an integrated semiconductor. In spite of the trend toward small portable terminals, one or more display devices installed in the portable terminals are required to promote user convenience.

In recent years, the display devices installed in the portable terminals are divided into a main display unit and a minor display unit, and therefore the display devices are generally mounted at both sides of the portable terminals. Here, the main display unit displays various images, including information on telecommunications, and the minor display unit displays simple information, such as a clock, a short message service (SMS), a ringer indicator, etc.

Also, flat panel displays, such as liquid crystal displays (LCDs), have been used as the display devices in portable terminals. The flat panel display has an advantage in that they take up less space because their thickness is small compared to a conventional cathode ray tube (CRT), and display conditions for the portable terminals are satisfied due to the low power consumption.

However, the minor display unit as configured conventionally has a disadvantage that its practical uses are limited due to its simple functions. Specifically, a user can only realize certain applications, such as menu selection, character transfer, digital multimedia broadcasting (DMB) reception, photography and video communications only through the main display unit. In the conventional unit, it is difficult for a user to realize the applications of the main display unit in the minor display unit, with the exception of the simple functions as described above.

### SUMMARY OF THE INVENTION

Accordingly, the present invention is designed to solve such drawbacks, and therefore an aim of the present invention is to provide an OLED display as a flat panel display provided in a portable terminal, the OLED display having a first display panel and a second display panel arranged on the same surface thereof, wherein information displayed on the two display panels is realized to be engaged with each other.

Also, another aim of the present invention is to provide an OLED display having a touch screen panel (TSP) arranged integrally on the first and second display panels.

One embodiment of the present invention is achieved by providing an OLED display including first and second display panels arranged on a same surface, a touch screen panel arranged integrally on the first and second display panels, a touch screen panel controller adapted to drive the touch screen panel and a display controller adapted to control the first and second display panels, the display controller being further adapted to separate information displayed on the display panels into an image signal and a data signal corresponding to the image signal, the display controller being further adapted to supply the separated image signal and data signal to the first and second display panels, respectively.

Each of the first and second display panels may include a first substrate, an image display unit including a plurality of thin film transistors and a light emitting element and an encapsulation substrate arranged on the first substrate, the encapsulation substrate being adapted to encapsulate the image display unit. The touch screen panel can be arranged integrally on the encapsulation substrate. The touch screen panel can include a transparent electrode arranged on one surface of the encapsulation substrate, a metal electrode arranged at edges of the transparent electrode and a polarizer film arranged on the encapsulation substrate. The touch screen panel can be driven in a capacitive manner.

As described above, the OLED display according to the present invention can be useful to promote portable terminal user's interests since the OLED display has a first display panel and a second display panel arranged in the same surface thereof, wherein information displayed on the two display panels is realized to be engaged with each other (i.e., information on the two displays are related and are not independent of each other).

Also, the OLED display according to the present invention can be useful to reduce the production cost, compared to the conventional OLED display in which a separate touch screen panel is arranged on each of the display panels, since a touch screen panel is arranged integrally on a large number of the display panels.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicated the same or similar components, wherein:

FIG. 1 is a schematic block diagram showing an OLED display according to one exemplary embodiment of the present invention; and

FIG. 2 is a cross-sectional view showing one region of first and second display panels and a touch screen panel of FIG. 1.

### DETAILED DESCRIPTION OF THE INVENTION

In the following detailed description, only certain exemplary embodiments of the present invention have been shown and described, simply by way of illustration. As those skilled in the art would realize, the described embodiments can be modified in various different ways, all without departing from the spirit or scope of the present invention. Accordingly, the drawings and description are to be regarded as illustrative in nature and not restrictive. In addition, when an element is referred to as being “on” another element, it can be directly on the element or be indirectly on the element with one or more intervening elements interposed therebetween. Also, when an element is referred to as being “connected to” another element, it can be directly connected to the element or be indirectly connected to the element with one or more intervening elements interposed therebetween. Hereinafter, like reference numerals refer to like elements.

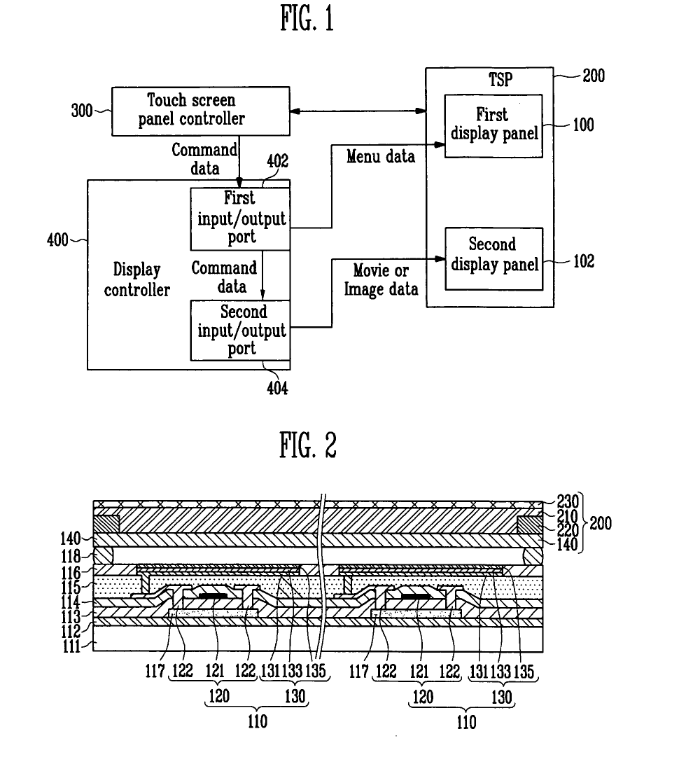

Turning now to FIG. 1, FIG. 1 is a schematic block diagram showing an organic light emitting display device (OLED display) according to one exemplary embodiment of the present invention. Referring to FIG. 1, the OLED display according to one exemplary embodiment of the present invention includes a first display panel 100 and a second display panel 102 arranged on the same surface thereof, a touch screen panel 200, a touch screen panel controller 300, and a display controller 400. Here, the touch screen panel 200 is arranged integrally on the first and second display panels, and the touch screen panel controller 300 drives the touch screen panel 200. The display controller 400 controls the first and second display panels 100, 102, separates information displayed on the display panels into an image signal and a data signal (i.e., text or menu data) corresponding to the image signal, and supplies the separated image signal and data signal to the first and second display panels 100, 102, respectively.

A schematic operation of the OLED display according to one exemplary embodiment of the present invention will now be described as follows. A broadcasting signal, received through a satellite wave or a ground wave, is inputted into the display controller 400 and separated into an image signal and a data signal (i.e., text or menu data) corresponding to the image signal by the display controller 400. Then, the data signal (e.g., a menu data signal) is transmitted to the first display panel 100 through a first input/output port 402 of the display controller 400 and displayed on an image display unit of the first display panel 100.

Then, when a menu screen is displayed on the image display unit provided in the first display panel 100, a user selects a certain item in the menu by contacting one region of the touch screen panel 200 that is arranged on the first display panel 100 so as to select a certain menu item on the menu screen. Then, the touch screen panel 200 transmits information on a contact point, for example, information (command data) on the selected menu option, to the touch screen panel controller 300. Therefore, the command data is inputted into the first input/output port 402 of the display controller 400. Then, the display controller 400 outputs the command data, inputted to the first input/output port 402, from the second input/output port 404. Therefore, an image or an image data corresponding to the command data is output to the second display panel 102.

As described above, a ground-wave or satellite mobile DMB TV can be displayed by outputting information on broadcasting channels and information on channel selection to the first display panel 100, selecting the channel and then viewing the channel on the second display panel 102. Also, when an idle screen or fonts are changed and used in the conventional display panels, a recent screen is changed into a new screen of each of the menus to check the newly set and changed image. In the present exemplary embodiment of the present invention, however, the second display panel 102 can display the changed image in real time according to the set environments of the first display panel 100 by realizing functions of the respective menus on the first display panel 100.

Also, when a caption that is output according to the image information is displayed on the second display panel 102 in viewing a moving picture, the caption translated into a second foreign language that a user wants to see can be output on the first display panel 100. Also, when information on an SMS message is received while viewing a moving image such as a movie or a music video, the conventional display devices should terminate a recently used function. However, the OLED display according to one exemplary embodiment of the present invention can solve the above problem by outputting and checking the information on an SMS message in the first display panel 100 without terminating the other application.

At this time, the first display panel 100 and the second display panel 102 can both be realized with organic light emitting display panels. Also, in the present invention, one touch screen panel 200 is arranged integrally on the first and second display panels, and this configuration will be described in more detail with reference to FIG. 2.

As described above, the OLED display according to one exemplary embodiment of the present invention can be useful to promote portable-terminal user convenience since the OLED display has a first display panel and a second display panel arranged on the same one surface thereof, wherein information displayed on the two display panels is realized to be engaged with each other. Therefore, the production cost can be reduced in the OLED display of the present invention when compared to conventional OLED displays that require a separate touch screen panel for each of the display panels.

Turning now to FIG. 2, FIG. 2 is a cross-sectional view showing one region of the touch screen panel 200 of FIG. 1. Referring to FIG. 2, the OLED display according to one exemplary embodiment of the present invention includes a first substrate 111 having image display units 110 of the first and second display panels 100, 102 arranged respectively therein; an encapsulation substrate 140 arranged on the first substrate 111 to encapsulate the image display unit 110 arranged on the first substrate 111, and a touch screen panel 200 arranged integrally on the encapsulation substrate 140.

At this time, FIG. 2 shows that the image display units 110, for the first and second display panels, are arranged on the same first substrate 111, and the same encapsulation substrate 140 is provided to encapsulate each of the image display units 110. However, this is merely one exemplary embodiment for convenience sake of the description, but the image display units of the first and second display panels can be arranged respectively on the separate substrates, and therefore the encapsulation substrate can also be arranged on separate substrates.

The touch screen panel 200 is characterized in that it is arranged integrally with both the first and second display panels 100, 102. In other words, touch screen panel 200 is arranged on the at least one encapsulation substrate. Each of the image display units 110 arranged respectively on the first substrate 111 includes a plurality of thin film transistors 120 and a plurality of light emitting elements 130. A buffer layer 112 and a semiconductor layer 117 are sequentially arranged on the first substrate 111, and a gate insulator 113, a gate electrode 121, an interlayer insulator 114, a source and drain electrode 123, and a passivation layer 115 are arranged on the semiconductor layer 117. At this time, the thin film transistor 120 includes a semiconductor layer 117, a gate electrode 120, a source and a drain electrode 122, and a light emitting element 130 arranged on the thin film transistor 120, the light emitting element 130 being electrically coupled to the thin film transistor 120 through a contact hole (not shown) arranged in the passivation layer 115.

The light emitting element 130 includes an anode electrode 131, a light emitting layer 133, and a cathode electrode 135. A pixel definition layer 116 is arranged on the anode electrode 131 and the passivation layer 115. Also, an encapsulation substrate 140 is arranged on the image display unit 110, including the thin film transistor 120 and the light emitting element 130, so as to encapsulate the thin film transistor 120 and the light emitting element 130 in addition to the first substrate 111. At this time, the first substrate 111 and the encapsulation substrate 140 are encapsulated by a sealant 118, and the encapsulation substrate 140 can be an insulating substrate such as transparent glass. A transparent moisture absorbing agent (not shown) can be arranged on the bottom surface of the encapsulation substrate 140 to absorb moisture that remains in a space between the encapsulation substrate 140 and the first substrate 111.

This exemplary embodiment of the present invention is characterized in that the touch screen panel 200 is arranged integrally on the encapsulation substrate 140, and therefore it is preferable that the touch screen panel 200 is driven in a capacitive manner. This means a transparent electrode 210 is coated on the encapsulation substrate 140 and a metal electrode 220 is arranged in edges or respective sides of the transparent electrode 210 in the case of the exemplary embodiment of FIG. 2.

At this time, indium tin oxide (ITO) is used as the transparent electrode 210. Also, the metal electrode 220 forms a resistor network around the transparent electrode 210. The resistor network is arranged in a linearization pattern to uniformly transmit a control signal to the entire surface of the transparent electrode 210.

Meanwhile, the metal electrode 220 can be made out of silver. The metal electrode 220 can be arranged by directly printing a silk screen on the transparent electrode 210 and heating the transparent electrode 210, or arranged by depositing a conventional conductive material on the transparent electrode 210 and patterning the conductive material.

In addition, a polarizer film 230 is arranged on the entire surface of the encapsulation substrate 140 including the metal electrode 220. The polarizer film 230 is flexible and functions to selectively transmit light entering from the outside. The visibility of images displayed through the OLED display can be improved by preventing the reflection of external light by including the polarizer film 230. Also, the polarizer film 230 prevents an electrical short of conductive styluses and fingers in the transparent electrode 210. Therefore, the capacitive touch screen panel 200 can detect a touch point in which a voltage drop occurs when the conductive styluses or the fingers are positioned on the polarizer film 230, or touch the polarizer film 230.

Meanwhile, the capacitive touch screen panel 200 is continuously charged and discharged. At this time, analog measurement circuits (current sensors) are coupled to four edges of the touch screen panel 200 to measure a charge capacity. This capacitive touch screen panel 200 is a bent or flat glass coated with a transparent metal oxide layer, and determines a touch point in which a voltage drop occurs when a voltage is applied to four corners of the touch screen panel 200 so that a uniform electric field can be arranged, and a picture is then drawn with the fingers and the conductive styluses.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. An organic light emitting display device (OLED display), comprising:
first and second display panels arranged on a same surface;
a touch screen panel arranged integrally on the first and second display panels;
a touch screen panel controller adapted to drive the touch screen panel; and
a display controller adapted to control the first and second display panels, the display controller being further adapted to separate information displayed on the display panels into an image signal and a data signal corresponding to the image signal, the display controller being further adapted to supply the separated image signal and data signal to the first and second display panels, respectively.

2. The OLED display of claim 1, wherein each of the first and second display panels comprises:
a first substrate;
an image display unit including a plurality of thin film transistors and a light emitting element; and
an encapsulation substrate arranged on the first substrate, the encapsulation substrate being adapted to encapsulate the image display unit.

3. The OLED display of claim 2, wherein the touch screen panel is arranged integrally on the encapsulation substrate.

4. The OLED display of claim 3, wherein the touch screen panel comprises:
a transparent electrode arranged on one surface of the encapsulation substrate;
a metal electrode arranged at edges of the transparent electrode; and
a polarizer film arranged on the encapsulation substrate.

5. The OLED display of claim 1, wherein the touch screen panel is driven in a capacitive manner.
